(19) United States
(12) Patent Application Publication
(10) Pub. No.: US 2015/0171224 A1
(43) Pub. Date: Jun. 18, 2015

(54) THIN FILM TRANSISTOR AND MANUFACTURING METHOD THEREOF, ARRAY SUBSTRATE AND DISPLAY DEVICE

(71) Applicant: BOE TECHNOLOGY GROUP CO., LTD., Beijing (CN)

(72) Inventors: Zheng Liu, Beijing (CN); Chunping Long, Beijing (CN); Jang Soon Im, Beijing (CN)

(21) Appl. No.: 14/124,104

(22) PCT Filed: Dec. 6, 2012
(86) PCT No.: PCT/CN2012/085988

§ 371 Date: Dec. 5, 2013

(30) Foreign Application Priority Data
Jul. 20, 2012 (CN) 201210254749.X

(51) Int. Cl. H01L 29/786; H01L 27/12

(52) U.S. Cl. CPC H01L 29/78606; H01L 27/1248

(57) ABSTRACT

Embodiments of the present invention relate to display technology field and provide a thin film transistor (1) and manufacturing method thereof, an array substrate, and a display device, and do not damage an active layer (12) of the thin film transistor while forming vias (16) over the source region (120) and the drain region (121) with via etching process. The thin film transistor (1) comprises a substrate (10), an active layer (12), a gate insulating layer (13), a gate (14) and an inter-layer insulating layer (17) disposed on the substrate (10), and further comprises: a conductive etching barrier layer (15) disposed on the active layer; the conductive etching barrier layer (15) being located to correspond to the source region (120) and the drain region (121) of the active layer (12) and vias (16) being formed over the source region (120) and the drain region (121) of the active layer (12) and not extending beyond edges of the conductive etching barrier layer (15).

### TECHNICAL FIELD

The present invention relates to a thin film transistor and a manufacturing method thereof, an array substrate and a display device.

### BACKGROUND

With continuous advancements of technologies, demands for liquid crystal display equipments are ever increasing, TFT-LCDs (Thin Film Transistor-Liquid Crystal Displays) have become mainstream of displays for mobile devices, such as mobile phones, flat computers, and etc. Furthermore, with the popularity of display devices, demands for colors of high quality, sharp contrast, great viewing angle, high response speed and low power dissipation are becoming more and more common, OLED (Organic Light-Emitting Diode) displays have attracted customers' interests.

As shown in FIG. 1, in prior art, one manufacturing method for thin film transistors is to successively deposit an active layer 12, a gate insulating layer 13, a gate electrode 14 and an inter-layer insulating layer 17 on a substrate 10, then etch vias 16 in corresponding areas over a source electrode 120 and a drain electrode 121 of the active layer 12 with via etching process (i.e., etching a portion of the gate insulating layer 13 and the inter-layer insulating layer 17). The vias 16 implement connections of the active layer 12 to external circuits by filling conductive electrode material in the vias 16.

However, the inventor found that it is impossible to make both the gate insulating layer and the inter-layer insulating layer completely uniform in thickness, and it is impossible for dry etching process to etch completely uniformly, hence leading to a phenomenon that some areas are etched exactly to the active layer and some have a portion of the active layer etched out or a portion of the insulating layer residual. This certainly causes non-uniform contact resistance of the active layer and the conductive electrode material, and even significant contact resistance in some portion, which influences switching characteristic of display devices using thin film transistors, and becomes more severe as substrates get larger.

### SUMMARY

Embodiments of the present invention provide a thin film transistor and manufacturing method thereof, an array substrate, and a display device, which do not damage the active layer while forming vias over the source region and the drain region with via etching process.

Embodiments of the present invention employ the following technical solutions:

a thin film transistor is provided that comprises a substrate, an active layer, a gate insulating layer, a gate electrode and an inter-layer insulating layer which are disposed on the substrate, and further comprises:

a conductive etching barrier layer disposed on the active layer; the conductive etching barrier layer being located to correspond to a source region and a drain region of the active layer and vias being formed over the source region and the drain region of the active layer and not extending beyond edges of the conductive etching barrier layer.

The active layer, the gate insulating layer, the gate electrode and the inter-layer insulating layer disposed on the substrate comprise:

the active layer disposed on the substrate;

the gate insulating layer disposed on the active layer and the substrate;

the gate electrode disposed on the gate insulating layer;

the inter-layer insulating layer disposed on the gate electrode and the gate insulating layer.

The conductive etching barrier layer is deposited between the active layer and the gate insulating layer.

The thin film transistor further comprises:

a buffer layer disposed between the substrate and the active layer.

The active layer, the gate insulating layer, the gate electrode and the inter-layer insulating layer disposed on the substrate comprise:

the gate electrode disposed on the substrate;

the gate insulating layer disposed on the gate electrode and the substrate;

the active layer disposed on the gate insulating layer;

the inter-layer insulating layer disposed on the active layer and the gate insulating layer.

The conductive etching barrier layer is disposed between the active layer and the inter-layer insulating layer.

The conductive etching barrier layer has a thickness in a range of 1500 Å to 3000 Å.

The present invention further provides an array substrate comprising thin film transistors with any features described above formed in array.

The present invention further provides a display device comprising the aforesaid array substrate.

The present invention further provides a manufacturing method for thin film transistor comprising forming an active layer, a gate insulating layer, a gate electrode and an inter-layer insulating layer on a substrate, and after forming the active layer the method further comprises:

forming a conductive etching barrier layer on the active layer, the conductive etching barrier layer being located to correspond to the source region and the drain region of the active layer;

after forming the inter-layer insulating layer the method further comprises:

forming vias over the source region and the drain region of the active layer with via etching process, the vias not extending beyond edges of the conductive etching barrier layer.

Forming a conductive etching barrier layer on the active layer comprises:

forming the conductive etching barrier layer with sputtering, thermal evaporation, plasma enhanced chemical vapor deposition (PECVD), low pressure chemical vapor deposition (LPCVD), atmosphere pressure chemical vapor deposition (APCVD) or electron cyclotron resonance chemical vapor deposition (ECR-CVD).

### BRIEF DESCRIPTION OF THE DRAWINGS

In order to clearly illustrate the technical solutions of the embodiments of the invention, the drawings of the embodiments will be briefly described in the following; it is obvious that the described drawings are only related to some embodiments of the invention and thus are illustrative rather than limiting to the invention.

FIG. 1 is a structural representation of a thin film transistor in the prior art;

FIG. 2 is a structural representation of a thin film transistor provided in the present invention;

FIG. 3 is a structural representation of another thin film transistor provided in the present invention;

FIG. 4 is a structural representation I of a thin film transistor in a thin film transistor manufacturing process provided in the present invention;

FIG. 5 is a structural representation II of a thin film transistor in a thin film transistor manufacturing process provided in the present invention;

FIG. 6 is a structural representation III of a thin film transistor in a thin film transistor manufacturing process provided in the present invention;

FIG. 7 is a structural representation IV of a thin film transistor in a thin film transistor manufacturing process provided in the present invention;

FIG. 8 is a structural representation V of a thin film transistor in a thin film transistor manufacturing process provided in the present invention;

FIG. 9 is a structural representation I of another thin film transistor in a thin film transistor manufacturing process provided in the present invention;

FIG. 10 is a structural representation II of another thin film transistor in a thin film transistor manufacturing process provided in the present invention;

FIG. 11 is a structural representation III of another thin film transistor in a thin film transistor manufacturing process provided in the present invention;

FIG. 12 is a structural representation IV of another thin film transistor in a thin film transistor manufacturing process provided in the present invention.

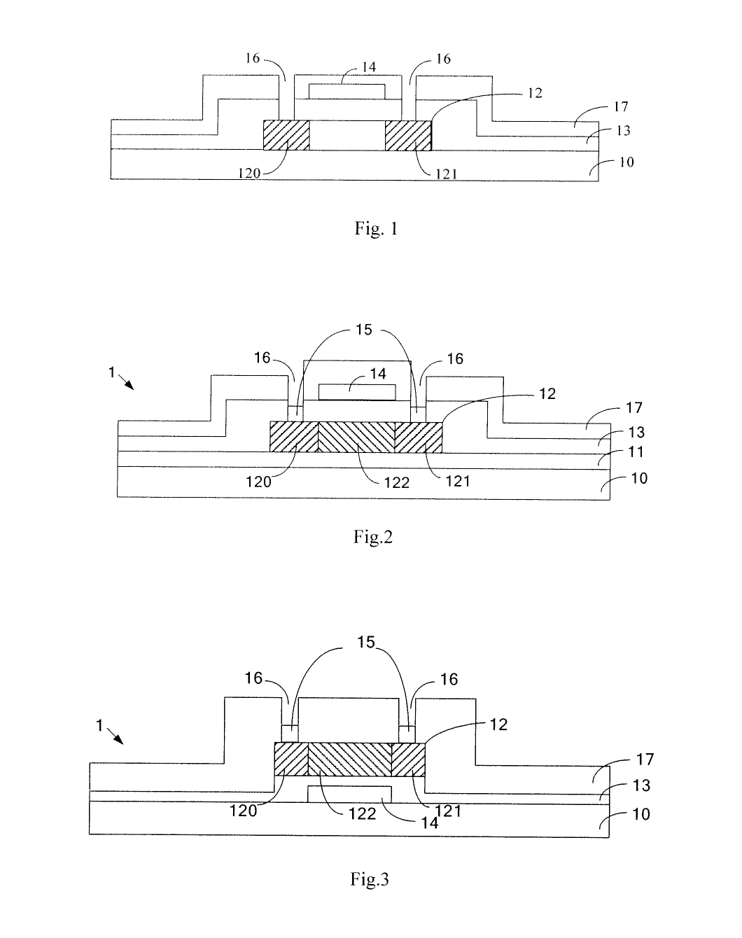

### DETAILED DESCRIPTION

In order to make objects, technical details and advantages of the embodiments of the invention apparent, the technical solutions of the embodiments will be described in a clearly and fully understandable way in connection with the drawings related to the embodiments of the invention. It goes without saying, the described embodiments are just a part but not all of the embodiments of the invention. Based on the described embodiments herein, those skilled in the art can obtain other embodiment(s), without any inventive work, which should be within the scope of the invention.

It should be noted that, the terms “above”, “over”, “on” and, “under” “below” in the present invention are only for the purpose of describing the present invention with reference to drawings, rather than being limiting terms.

The thin film transistor provided in embodiments of the present invention comprises a substrate, an active layer, a gate insulating layer, a gate electrode and an inter-layer insulating layer disposed on the substrate, and further comprises:

a conductive etching barrier layer disposed on the active layer; wherein the conductive etching barrier layer is located to correspond to an source region and a drain region of the active layer and vias are formed over the source region and the drain region of the active layer, not extending beyond edges of the conductive etching barrier layer.

As an example, the active layer, the gate insulating layer, the gate electrode and the inter-layer insulating layer disposed on the substrate comprise:

the active layer disposed on the substrate;

the gate insulating layer disposed on the active layer and the substrate;

the gate electrode disposed on the gate insulating layer;

the inter-layer insulating layer disposed on the gate electrode and the gate insulating layer.

Further, the conductive etching barrier layer is disposed between the active layer and the gate insulating layer.

As shown in FIG. 2, a thin film transistor 1 provided in one embodiment of the present invention may comprises:

a substrate 10, of which the material may be non-alkali glass due to high content of metal impurities in alkali glass, such as aluminum, barium and sodium, that are prone to diffuse during high temperature processing;

for example, a buffer layer 11 may be disposed on the substrate 10 to block diffusion of impurities in the substrate 10 into the active layer 12 and prevent characteristics of TFT elements such as threshold voltage and leakage current from being impacted;

an active layer 12 disposed on the buffer layer 11, which provides a source region 120, a drain region 121 and a channel region 122;

a conductive etching barrier layer 15 disposed on the active layer 12; wherein the conductive etching barrier layer 15 is located to correspond to an source region 120 and a drain region 121 of the active layer 12 and vias 16 are formed over the source region 120 and the drain region 121 of the active layer 12 which do not extend beyond edges of the conductive etching barrier layer 15.

It is understood that the above-mentioned “vias not extending beyond edges of the conductive etching barrier layer” means that edges of shadows of the vias projected onto the conductive etching barrier layer do not extend beyond edges of the conductive etching barrier layer. In general, the vias are of cylinder shape. However, there is no limitation for shapes of the conductive etching barrier layer in embodiments of the present invention. That is, the conductive etching barrier layer may be of circle or polygon, as long as it ensures that vias do not extend beyond edges of the conductive etching barrier layer.

It is to be noted that, in practical applications, it is allowed that vias go slightly beyond edges of the conductive etching barrier layer, since etching gases can not be easily controlled while etching vias, therefore adaptive change may be made according to process requirements.

It is further noted that, although embodiments of the present invention do not impose any limitation to shapes of the conductive etching barrier layer, the conductive etching barrier layer may cover the source region and the drain region of the active layer as much as possible, but may not extend beyond corresponding regions of the source region and the drain region, since the more the contact area, the smaller the contact resistance, and the better the conductive performance.

A gate insulating layer 13 disposed on the buffer layer 11, the active layer 12 and the conductive etching barrier layer 15;

a gate electrode 14 disposed on the gate insulating layer 13, the gate electrode 14 being over the active layer 12;

an inter-layer insulating layer 17 disposed on the gate electrode 14 and the gate insulating layer 13.

For example, the material for the buffer layer 11 is silicon oxide and/or silicon nitride.

For example, the buffer layer 11 has a thickness in range of 500 Å to 4000 Å.

As an example, the active layer, gate insulating layer, gate electrode and inter-layer insulating layer disposed on the substrate include:

the gate electrode disposed on the substrate;

the gate insulating layer disposed on the gate electrode and the substrate;

the active layer disposed on the gate insulating layer;

the inter-layer insulating layer disposed on the active layer and the gate insulating layer.

Further, the conductive etching barrier layer is disposed between the active layer and the inter-layer insulating layer.

As shown in FIG. 3, another thin film transistor 1 provided in embodiments of the present invention may comprise:

a substrate 10, of which the material may be non-alkali glass due to high content of metal impurities in alkali glass, such as aluminum, barium and sodium, that are prone to diffuse during high temperature processing;

a gate electrode 14 disposed on the substrate 10;

a gate insulating layer 13 disposed on the substrate 10 and the gate electrode 14;

an active layer 12 disposed on the gate insulating layer 13, which is located over the gate electrode 14 and provides a source region 120, a drain region 121 and a channel region 122;

a conductive etching barrier layer 15 disposed on the active layer 12; wherein the conductive etching barrier layer 15 is located to correspond to an source region 120 and a drain region 121 of the active layer 12 and vias 16 are formed over the source region 120 and the drain region 121 of the active layer 12 which do not extend beyond edges of the conductive etching barrier layer 15;

an inter-layer insulating layer 17 disposed on the active layer 12, a gate insulating layer 13 and a conductive etching barrier layer 15.

It is noted that the only difference between the two thin film transistors provided in FIGS. 2 and 3 lies in that, the thin film transistor of FIG. 2 has a “top gate” structure with an active layer disposed between the substrate and the gate insulating layer on which the gate electrode is formed, while the thin film transistor of FIG. 3 has a “bottom gate” structure with a gate insulating layer covering the gate electrode and an active layer disposed on the gate insulating layer. That is, the method proposed in embodiments of the present invention, in which a conductive etching barrier layer is added on the active layer, is applicable both to a “top gate” thin film transistor and to a “bottom gate” thin film transistor.

For example, the active layer has a thickness in range of 500 Å to 1000 Å.

For example, the conductive etching barrier layer has a thickness of 1000 Å to 7000 Å. For example, the conductive etching barrier layer has a thickness of 1500 Å to 3000 Å.

It is further noted that, non-alkali glass refers to glass that can reduce contraction generated during heating without significantly changing strain point. The non-alkali glass is characterized in that a ratio (Δan-st/α50-350) of the gradient of equilibrium density curve Δan-st (ppm/° C.) in the temperature range from around the annealing point (Tan) to around the strain point (Tst) to the average coefficient of linear expansion α50-350(×10⁻⁶/° C.) at 50˜350° C. is greater than or equal to 0 and smaller than 3.64.

The thin film transistor provided in the present invention comprises a substrate, an active layer, a gate insulating layer, a gate electrode and an inter-layer insulating layer disposed on the substrate, and further comprises a conductive etching barrier layer disposed on the active layer, wherein the conductive etching barrier layer is located to correspond to the source region and the drain region of the active layer, and vias do not extend beyond edges of the conductive etching barrier layer while forming vias over the source region and the drain region with via etching process. With this solution, since a conductive etching barrier layer is added on the source region and the drain region of the active layer, when etching vias in corresponding areas over the source and the drain of the active layer with via etching process, i.e., etching a portion of the gate insulating layer and the inter-layer insulating layer, etching gases can hardly etch the conductive etching barrier layer and vias can not damage the active layer, avoiding active layer being etched out or not etching to the active layer in prior arts and hence leading non-uniform contact resistance between the active layer and the conductive electrode material.

A manufacturing method for thin film transistor provided in embodiments of the present invention comprises forming an active layer, a gate insulating layer, a gate electrode and an inter-layer insulating layer on a substrate, and further comprises after forming the active layer:

forming a conductive etching barrier layer on the active layer, the conductive etching barrier layer being located to correspond to the source region and the drain region of the active layer;

further comprises after forming the inter-layer insulating layer:

forming vias over the source region and the drain region of the active layer with via etching process, the vias not extending beyond edges of the conductive etching barrier layer.

Corresponding to the “top gate” thin film transistor in the above-mentioned embodiment, as an example, the forming an active layer, a gate insulating layer, a gate electrode and an inter-layer insulating layer on a substrate comprises:

forming the active layer on the substrate;

forming the gate insulating layer on the active layer and the substrate;

forming the gate electrode on the gate insulating layer;

forming the inter-layer insulating layer on the gate electrode and the gate insulating layer.

The manufacturing method for thin film transistor comprises:

S101, providing a substrate.

It is to be further noted that the substrate may be non-alkali glass due to high content of metal impurities in alkali glass, such as aluminum, barium and sodium, that are prone to diffuse during high temperature processing.

S102, forming a buffer layer on the substrate.

As shown in FIG. 4, on the pre-cleaned substrate 10, a buffer layer 11 is formed with plasma enhanced chemical vapor deposition (PECVD) to block diffusion of impurities in the substrate 10 into the active layer and prevent characteristics of TFT such as threshold voltage and leakage current from being influenced. The method for forming a buffer layer 11 on the substrate 10 may further comprise low pressure chemical vapor deposition (LPCVD), atmospheric pressure chemical vapor deposition (APCVD), electron cyclotron resonance-chemical vapor deposition (ECR-CVD) or sputtering, and etc.

It is to be further noted that, the material for the buffer layer 11 is silicon oxide and/or silicon nitride, that is, the buffer layer 11 may be a single layer of silicon oxide, silicon nitride or lamination of both.

Furthermore, the buffer layer 11 may have a thickness of 300 Å to 10000 Å, for example, the buffer layer 11 has a thickness of 500 Å to 4000 Å, and the temperature for depositing the buffer layer 11 is not greater than 600° C., i.e., the deposition temperature is 600° C. or lower.

It is to be noted that the buffer layer 11 may not be provided. For example, a buffer layer 11 is disposed on the substrate 10 to block diffusion of impurities in the substrate 10 into the active layer 12 and prevent characteristics of TFT elements such as threshold voltage and leakage current from being impacted.

S103, forming an active layer on the buffer layer.

As an example, the method for forming an active layer on the buffer layer may comprise:

as shown in FIG. 5, a non-crystalline silicon film is deposited on the buffer layer 11 using PECVD, LPCVD or sputtering method and is patterned to form an active layer 12. Specifically, deposition is performed on the buffer layer 11, a mask is formed with photolithographic process, and then patterns are formed with dry etching process to form an active layer 12, with the deposition temperature not higher than 600° C. It is also possible to deposit a microcrysalline silicon film with PECVD, LPCVD or sputtering method and pattern it to form the active layer 12.

It is to be further noted that many chip process steps in semiconductor manufacturing use the photolithographic technology. Pattern “negatives” for these steps are referred to as a mask. The mask functions to mask an opaque pattern template in a selected area on the silicon wafer, then erosions or diffusions to be followed will only influence areas other than the selected area.

S104, forming a conductive etching barrier layer on the active layer, the conductive etching barrier layer being located to correspond to the source region and the drain region of the active layer.

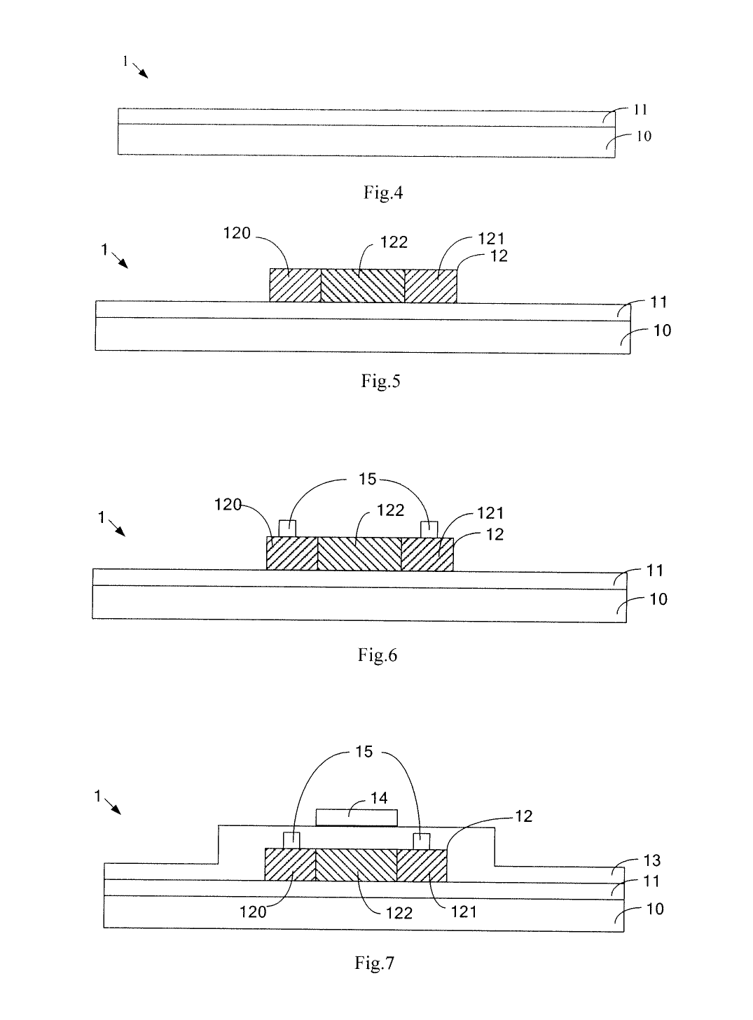

As shown in FIG. 6, a conductive etching barrier layer 15 is formed on the source 120 and the drain 121 of the active layer 12. The method for forming the conductive etching barrier layer 15 may comprise depositing conducting material on the source region 120 and the drain region 121 of the active layer 12 with sputtering to form the conductive etching barrier layer 15. The conducting material may be metal, metal alloy or conducting metal oxide, such as molybdenum, molybdenum alloy or indium gallium zinc oxide (IGZO). The conductive etching barrier layer 15 may have a thickness of 1000 Å to 7000 Å. For example, the conductive etching barrier layer 15 may have a thickness of 1500 Å to 3000 Å. Depositing conducting material to form the conductive etching barrier layer 15 may further comprise thermal evaporation, PECVD, LPCVD, APCVD or ECR-CVD, etc.

S105, forming a gate insulating layer and a gate electrode on the active layer, the buffer layer and the conductive etching barrier layer.

As shown in FIG. 7, a gate insulating layer 13 is formed on the active layer 12, the buffer layer 11 and the conductive etching barrier layer 15 with PECVD, LPCVD, APCVD or ECR-CVD, and etc. A gate electrode film is deposited on the gate insulating layer 13 with sputtering, thermal evaporation or PECVD, LPCVD, APCVD, ECR-CVD, and etc., and patterned with wet or dry etching method by means of photolithographic process to form a gate electrode 14. The gate insulating layer 13 may have a thickness of 300 Å to 3000 Å. An appropriate thickness may also be selected according to specific process requirements, there is no limitation set forth in the present invention. For the gate insulating layer 13, a single layer of silicon oxide, silicon nitride or lamination of both may be used, and the temperature for depositing gate insulating layer 13 may be below 600° C. The gate electrode 14 may be formed by conducting material such as metal, metal alloy such as molybdenum and molybdenum alloy or doped polysilicon. The gate electrode 14 may have a thickness in a range of 1000 Å to 8000 Å, for example, the gate electrode 14 may have a thickness in a range of 2500 Å to 4000 Å.

S106, forming an inter-layer insulating layer on the gate electrode and the gate insulating layer.

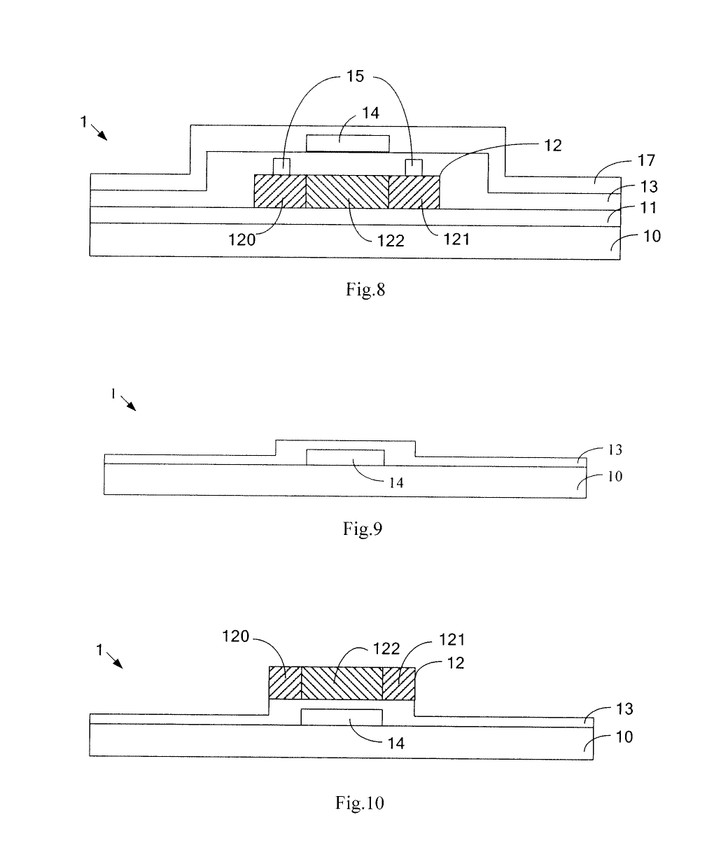

As shown in FIG. 8, an inter-layer insulating layer 17 may be formed on the gate electrode 14 and the gate insulating layer 13 under a deposition temperature below 600° C. with PECVD, LPCVD, APCVD or ECR-CVD and etc. The inter-layer insulating layer 17 may be formed of a single layer of silicon oxide or a lamination of silicon oxide and silicon nitride.

S107, vias are formed over the source region and the drain region with via etching process.

The vias do not extend beyond edges of the conductive etching barrier layer.

For example, the via process may be performed on the conductive etching barrier layer corresponding to the source region and the drain region to facilitate controlling size and depth of the vias.

As shown in FIG. 2, a layer of photoresist as a mask is coated on the inter-layer insulating layer 17, wherein the photoresist may have a thickness of 10000 to 20000, vias 16 are formed over the source region 120 and the drain region 121 with dry etching, wherein plasma etching, reactive ion etching and inductively coupled plasma etching and etc. may be used as dry etching, etching gases may be gases containing fluorine and chlorine, such as CF₄, CHF₃, SF₆, CCl₂F₂ or mixture of these gases with O₂.

As can be seen in FIG. 2, since the active layer 12 has a conductive etching barrier layer 15 added, the etching gas etches the conductive etching barrier layer 15 very slowly and with a negligible etched amount, such that vias 16 do not extend beyond the conductive etching barrier layer 15 while forming vias 16 over the source region 120 and the drain region 121 with via etching process, then it is possible to avoid a portion of the active layer 12 being etched or a portion of the gate insulating layer being residual due to the non-uniformity of the gate insulating layer 13 and/or the inter-layer insulating layer 17.

So far, the thin film transistor with “top gate” structure as shown in FIG. 2 is manufactured.

Corresponding to the “bottom gate” thin film transistor in the above-mentioned embodiment, as an example, the forming an active layer, a gate insulating layer, a gate electrode and an inter-layer insulating layer on the substrate comprises:

forming the gate electrode on the substrate;

forming the gate insulating layer on the gate electrode and the substrate;

forming the active layer on the gate insulating layer;

forming the inter-layer insulating layer on the active layer and the gate insulating layer.

The manufacturing method for thin film transistor comprises:

S201, providing a substrate.

It is to be further noted that the substrate may be non-alkali glass due to high content of metal impurities in alkali glass such as aluminum, barium and sodium that are prone to diffuse during high temperature processing.

S202, forming the gate electrode and the gate insulating layer on the substrate.

As shown in FIG. 9, to manufacture a thin film transistor with “bottom gate” structure, a gate electrode 14 needs to be formed on the substrate 10 first. The method for forming the gate insulating layer 13, the gate insulating layer 13, the gate electrode 14 on the substrate 10 and the gate electrode 14 is similar to that of forming the gate insulating layer 13, the gate electrode 14 in manufacturing a thin film transistor with “top gate” structure, hence detailed description will be omitted.

S203, forming an active layer on the gate insulating layer.

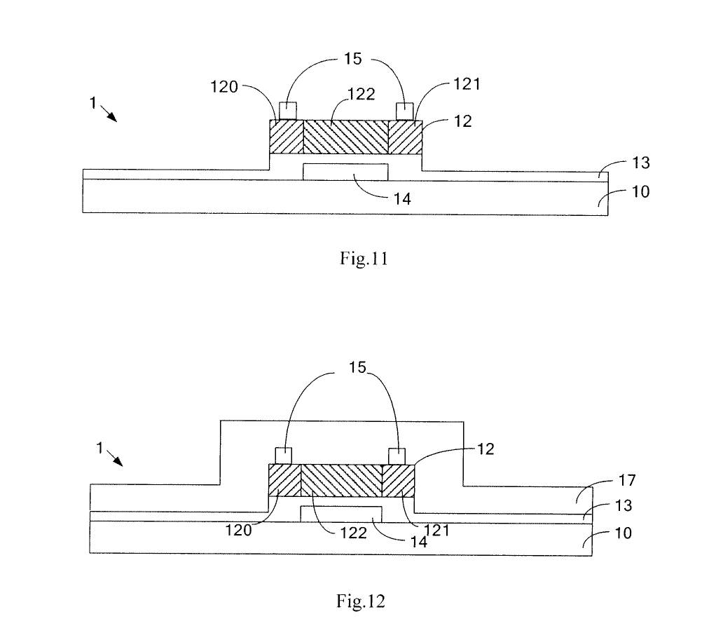

Like the method for forming the active layer 12 in manufacturing a thin film transistor with “top gate” structure, as shown in FIG. 10, an active layer 12 is formed on the gate insulating layer 13.

S204, forming a conductive etching barrier layer on the active layer, the conductive etching barrier layer being located to correspond to the source region and the drain region of the active layer.

Like the step S104, as shown in FIG. 11, a conductive etching barrier layer 15 is formed on the source region 120 and the drain region 121 on the active layer 12, which will not be described further.

S205, forming an inter-layer insulating layer on the active layer and the conductive etching barrier layer.

As shown in FIG. 12, the inter-layer insulating layer 17 may be formed on the active layer 12 and the conductive etching barrier layer 15 under a deposition temperature below 600° C. with PECVD, LPCVD, APCVD or ECR-CVD. The inter-layer insulating layer 17 may be formed of a single layer of silicon oxide or a lamination of silicon oxide and silicon nitride.

S206, vias are formed over the source region and the drain region with via etching process.

The vias do not extend beyond edges of the conductive etching barrier layer.

For example, the via process may be performed on the conductive etching barrier layer corresponding to the source region and the drain region to facilitate controlling size and depth of the vias.

As shown in FIG. 3, a layer of photoresist as a mask is coated on the inter-layer insulating layer 17, wherein the mask may have a thickness of 10000 Å to 20000 Å. Vias 16 are formed over the source region 120 and the drain region 121 with dry etching process. Plasma etching, reactive ion etching and inductively coupled plasma etching may be used as dry etching method. The etching gas may be gas containing fluorine and chlorine such as CF₄, CHF₃, SF₆, CCl₂F₂ or mixture of these gases with O₂.

As can be seen in FIG. 3, since the active layer 12 has a conductive etching barrier layer 15 added, the etching gas etches the conductive etching barrier layer 15 very slowly and with a negligible etched amount, such that vias 16 do not extend beyond the conductive etching barrier layer 15 while forming vias 16 over the source region 120 and the drain region 121 with via etching process, then it is possible to avoid a portion of the active layer 12 being etched or a portion of the gate insulating layer being residual due to the non-uniformity of the gate insulating layer 13 and/or the inter-layer insulating layer 17.

So far, the thin film transistor with “bottom gate” structure as shown in FIG. 3 is manufactured.

With the thin film transistor manufacturing method provided in the present invention, by forming an active layer, a gate insulating layer, a gate electrode and an inter-layer insulating layer on the substrate, and further forming a conductive etching barrier layer on the active layer, wherein the conductive etching barrier layer is located to correspond to the source region and the drain region of the active layer, and forming vias not extending beyond edges of the conductive etching barrier layer while forming vias over the source region and the drain region with via etching process, a thin film transistor is formed. With this solution, since a conductive etching barrier layer is added on the source region and the drain region of the active layer, when etching vias in corresponding areas over the source and the drain of the active layer with via etching process, i.e., etching a portion of the gate insulating layer and the inter-layer insulating layer, etching gases can hardly etch the conductive etching barrier layer and vias can not damage the active layer, avoiding a portion of active layer being etched out or not etching to the active layer in prior arts and hence leading non-uniform contact resistance between the active layer and the conductive electrode material.

Embodiments of the present invention provide an array substrate comprising thin film transistors with any features described in the above-mentioned embodiments formed in array, thin film transistors being identical with those in the above-mentioned embodiments and will not be further described.

Embodiments of the present invention provide a display device having an array substrate with any feature described in the above-mentioned embodiments. The display device may be a liquid crystal display device comprising a color filter substrate and the array substrate provided in the above-mentioned embodiments disposed parallel with each other, and liquid crystal filled in between the color filter substrate and the array substrate. The display device may also be an OLED display device including an array substrate provided in the above-mentioned embodiments and organic luminescent material evaporated on the array substrate as well as a package cover.

The liquid crystal display device provided in embodiments of the present invention may be any product with display function such as a liquid crystal display, a liquid crystal TV, a digital picture frame, a mobile phone, a flat computer. There is no limitation for the present invention.

Embodiments according to the present invention may at least provide the following structures and methods:

(1) A thin film transistor comprising a substrate, an active layer, a gate insulating layer, a gate electrode and an inter-layer insulating layer disposed on the substrate, and further comprising:

a conductive etching barrier layer disposed on the active layer; the conductive etching barrier layer being located to correspond to an source region and a drain region of the active layer and vias being formed over the source region and the drain region of the active layer and not extending beyond edges of the conductive etching barrier layer.

(2) The thin film transistor according to (1), wherein, the active layer, the gate insulating layer, the gate electrode and the inter-layer insulating layer disposed on the substrate comprise:

the active layer disposed on the substrate;

the gate insulating layer disposed on the active layer and the substrate;

the gate electrode disposed on the gate insulating layer;

the inter-layer insulating layer disposed on the gate electrode and the gate insulating layer.

(3) The thin film transistor according to (1) or (2), wherein, the conductive etching barrier layer is disposed between the active layer and the gate insulating layer.

(4) The thin film transistor according to any one of (1) to (3), further comprising:

a buffer layer disposed between the substrate and the active layer.

(5) The thin film transistor according to any one of (1) to (4), wherein the active layer, the gate insulating layer, the gate electrode and the inter-layer insulating layer disposed on the substrate comprise:

the gate electrode disposed on the substrate;

the gate insulating layer disposed on the gate electrode and the substrate;

the active layer disposed on the gate insulating layer;

the inter-layer insulating layer disposed on the active layer and the gate insulating layer.

(6) The thin film transistor according to any one of (1) to (5), wherein, the conductive etching barrier layer is disposed between the active layer and the inter-layer insulating layer.

(7) The thin film transistor according to any one of (1) to (6), wherein, the conductive etching barrier layer has a thickness of 1500 Å to 3000 Å.

(8) An array substrate comprising an array formed of the thin film transistors according to any one of (1) to (7).

(9) A display device comprising an array substrate according to (8).

(10) A manufacturing method for a thin film transistor comprising forming an active layer, a gate insulating layer, a gate electrode and an inter-layer insulating layer on a substrate, wherein

after forming the active layer, further comprising:

forming a conductive etching barrier layer on the active layer, the conductive etching barrier layer being located to correspond to the source region and the drain region of the active layer;

after forming the inter-layer insulating layer further comprising:

forming vias over the source region and the drain region of the active layer with via etching process, the vias not extending beyond edges of the conductive etching barrier layer.

(11) The manufacturing method for a thin film transistor of (10), wherein, forming a conductive etching barrier layer on the active layer comprises:

forming the conductive etching barrier layer with sputtering, thermal evaporation, plasma enhanced chemical vapor deposition, low pressure chemical vapor deposition, atmosphere pressure chemical vapor deposition or electron cyclotron resonance chemical vapor deposition.

What are described above is related to the illustrative embodiments of the disclosure only and not limitative to the scope of the disclosure; the scopes of the disclosure are defined by the accompanying claims.

1. A thin film transistor comprising a substrate, an active layer, a gate insulating layer, a gate electrode and an inter-layer insulating layer disposed on the substrate, and further comprising:
a conductive etching barrier layer disposed on the active layer; the conductive etching barrier layer being located to correspond to a source region and a drain region of the active layer, vias being formed over the source region and the drain region of the active layer and not extending beyond edges of the conductive etching barrier layer.

2. The thin film transistor according to claim 1, wherein, the active layer, the gate insulating layer, the gate electrode and the inter-layer insulating layer disposed on the substrate comprise:
the active layer disposed on the substrate;
the gate insulating layer disposed on the active layer;
the gate electrode disposed on the gate insulating layer;
the inter-layer insulating layer disposed on the gate electrode and the gate insulating layer.

3. The thin film transistor according to claim 1, wherein, the conductive etching barrier layer is disposed between the active layer and the gate insulating layer.

4. The thin film transistor according to claim 1, further comprising:
a buffer layer disposed between the substrate and the active layer.

5. The thin film transistor according to claim 1, wherein, the active layer, the gate insulating layer, the gate electrode and the inter-layer insulating layer disposed on the substrate comprise:
the gate electrode disposed on the substrate;
the gate insulating layer disposed on the gate electrode and the substrate;
the active layer disposed on the gate insulating layer;
the inter-layer insulating layer disposed on the active layer and the gate insulating layer.

6. The thin film transistor according to claim 1, wherein, the conductive etching barrier layer is disposed between the active layer and the inter-layer insulating layer.

7. The thin film transistor according to claim 1, wherein, the conductive etching barrier layer has a thickness in a range of 1500 Å to 3000 Å.

8. An array substrate comprising an array formed of the thin film transistors according to claim 1.

9. A display device comprising an array substrate according to claim 8.

10. (canceled)

11. (canceled)
